(19) United States
(12) Patent Application Publication
(10) Pub. No.: US 2014/0161990 A1
(43) Pub. Date: Jun. 12, 2014

(54) Anti-Glare Glass/Substrate Via Novel Specific Combinations of Dry and Wet Processes

(71) Applicant: INTERMOLECULAR, INC., San Jose, CA (US)

(72) Inventors: Nikhil Kalyankar, Mountain View, CA (US); Scott Jewhurst, Redwood City, CA (US); Minh Huu Le, San Jose, CA (US)

(73) Assignee: INTERMOLECULAR, INC., San Jose, CA (US)

(21) Appl. No.: 13/711,986

(22) Filed: Dec. 12, 2012

(51) Int. Cl. C23C 16/44

(52) U.S. Cl. CPC C23C 16/44
USPC 427/569; 427/162

(57) ABSTRACT

Methods for depositing layers by PVD, wherein the PVD process parameters are selected to impart porosity in the layer are described. The porous layers are then exposed to a vapor or liquid binder material to fill the pores and increase the mechanical strength of the layer and the adhesion of the layer. Optionally, a curing step may be applied to the layer. Methods for depositing polycrystalline metal oxide layers using PVD or CVD are described. Optionally, the layers are exposed to an anneal step. The polycrystalline metal oxide layers are then exposed to a vapor or liquid texturing reagent to texture the surface of the layer.

### TECHNICAL FIELD

The present invention relates to optical coatings. More particularly, this invention relates to optical coatings that improve, for example, the anti-glare performance of transparent substrates and methods for forming such optical coatings.

### BACKGROUND

Anti-glare coatings, and anti-glare panels in general, are desirable in many applications including semiconductor device manufacturing, solar cell manufacturing, glass manufacturing, and display screen manufacturing. Such optical coatings scatter specular reflections into a wide viewing cone to diffuse glare and reflection. It is difficult to achieve a substrate that simultaneously reduces gloss (i.e., specular reflection) and haze (i.e., diffuse transmittance) while relying on light scattering to obtain anti-glare properties.

Conventional methods of forming anti-glare panels include, for example, wet etching the surface of the substrate, using mechanical rollers with pre-defined textures on substrates to create a surface roughness, and applying thin, polymeric films with texture to the substrates using adhesives. Such methods are expensive, have low throughput (i.e., a low rate of manufacture), and lack precise control with respect to surface texture, which results in a diffuse scattering coating with poor light transmittance. Additionally, coatings formed using the polymeric films often demonstrate poor abrasion resistance and cohesive strength, resulting in the coatings (and/or the substrate itself) being damaged when various forces are experienced.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments, methods for depositing layers by PVD, wherein the PVD process parameters are selected to impart porosity in the layer are described. The porous layers are then exposed to a vapor or liquid binder material to fill the pores and increase the mechanical strength of the layer and the adhesion of the layer. Optionally, a curing step may be applied to the layer. Methods for depositing polycrystalline metal oxide layers using PVD or CVD are described. Optionally, the layers are exposed to an anneal step. The polycrystalline metal oxide layers are then exposed to a vapor or liquid texturing reagent to texture the surface of the layer.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a cross-sectional schematic of a substrate with a porous film formed thereon.

FIG. 2 illustrates a cross-sectional schematic of a substrate with a porous film formed thereon.

FIG. 3 illustrates a cross-sectional schematic of a substrate with a porous film formed thereon.

FIGS. 4A and 4B illustrate a cross-sectional schematic of a substrate with a polycrystalline film formed thereon.

FIGS. 5A and 5B illustrate a cross-sectional schematic of a substrate with a polycrystalline film formed thereon.

FIGS. 6A and 6B illustrate a cross-sectional schematic of a substrate with a polycrystalline film formed thereon.

FIGS. 7A and 7B illustrate a PVD system according to some embodiments.

FIG. 8 illustrates an in-line PVD system according to some embodiments.

FIG. 9 illustrates a flow chart describing methods according to some embodiments.

FIG. 10 illustrates a flow chart describing methods according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

As used herein, PVD processes will be understood to include common deposition processes such as sputtering, evaporation, laser ablation deposition, ion beam deposition, and the like. In the discussion to follow, sputtering will be used as an example, but those skilled in the art will understand that the methods may be applied to any of the PVD techniques listed herein.

In some embodiments, methods are provided that produce coatings that offer anti-glare properties as a result of surface roughness incorporated into the layer during the deposition process. Typically, PVD processes are developed to produce uniform layers having high density and uniform properties throughout the thickness of the layer. In some embodiments, the process parameters of the PVD process (e.g. sputtering) are purposely “de-tuned” to produce layers that exhibit high surface roughness and inhomogeneous properties (e.g. density, refractive index, composition, and the like) throughout the thickness of the layer. As an example, the angle of the vapor flux incident on the substrate surface can be changed to alter the density of layers formed using a PVD (e.g. sputtering) process. The substrate can be tilted such that the angle of the arriving flux forms an oblique angle to the substrate. This will result in the formation of nano-columnar growth that will form a layer with high surface roughness and porosity within the layer.

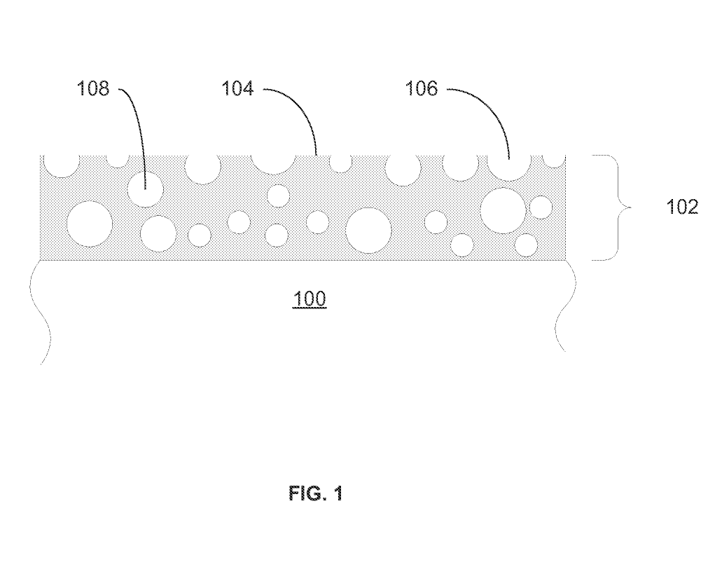

FIG. 1 illustrates a cross-sectional schematic of a substrate with a porous layer formed thereon. FIG. 1 is meant to depict a substrate, 100, with a layer, 102, formed thereon using a PVD process (e.g. sputtering). The layer, 102, includes a matrix, 104, (formed from the deposited material), the matrix including internal porosity, 108, and surface porosity, 106. Although illustrated as circles/spheres, those skilled in the art will understand that the pores within the material will generally have irregular shapes. As discussed previously, the size and volume fraction of the porosity within the layer can be influenced by changing the process parameters of the PVD process. Examples of process parameters that will influence the size and volume fraction of the porosity within the layer include flux angle, power, plasma frequency (e.g. radio frequency (RF) versus direct current (DC), pressure, substrate temperature, sputtering gas composition, target-to-substrate spacing, and the like.

The surface porosity, 106, is formed by the intersection of pores within the matrix with the surface. For applications where the goal is to produce layers that serve as anti-glare coatings in the visible range, the root mean square (rms) surface roughness should be between 0.4 microns and 5.0 microns. Typically, the layer, 102, has a thickness between 1 micron and 50 microns. Examples of suitable materials include transparent oxides, nitrides, or oxy-nitrides of aluminum, boron, silicon, tin, titanium, zinc, or any combination thereof. The layer may be deposited using a reactive deposition process (e.g. reactive sputtering), or may be deposited using a target manufactured from the desired material (e.g. a metal oxide target). The layer may be formed as a homogeneous matrix or may be formed from a plurality of thin layers (e.g. a nanolaminate).

Although the layers described with reference to FIG. 1 may have useful anti-glare properties, they will be mechanically weakened and may have poor adhesion to the substrate compared to a fully dense coating due to the porosity. Therefore, the layers can be damaged more easily and can be removed more easily by abrasion than fully dense coatings.

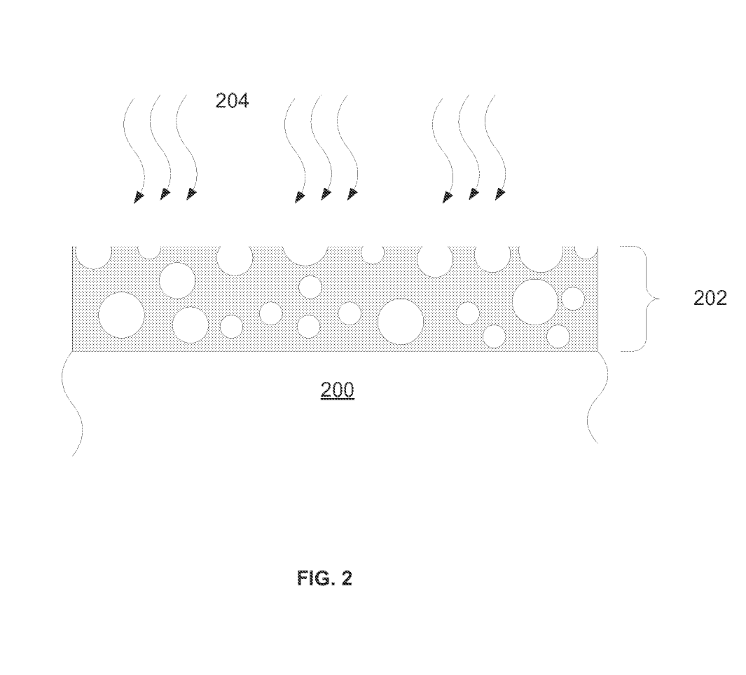

FIG. 2 illustrates a cross-sectional schematic of a substrate with a porous film formed thereon. FIG. 2 is meant to depict a substrate, 200, with a layer, 202, formed thereon using a PVD process (e.g. sputtering). To increase the mechanical strength and adhesion of the layer, the layer, 202, may be exposed to a binder material, 204. The binder material, 204, may be applied in vapor or liquid form. The binder material will penetrate into the layer and fill the pores, adding mechanical strength to the layer and improving the adhesion. Examples of suitable binder materials include one or more of inorganic silanes, organic silanes, silane vapors, siloxanes, silazanes, sol formulations containing silanes, reactive silsesquioxanes or combinations thereof. There are additional binder materials such as that are suitable for material systems that are not silicon specific. An optional anneal or curing step may be imposed after the binder material has impregnated the layer to further add mechanical strength to the layer. The curing step may be a thermal curing process, a chemical curing process, radiation curing process or a combination thereof.

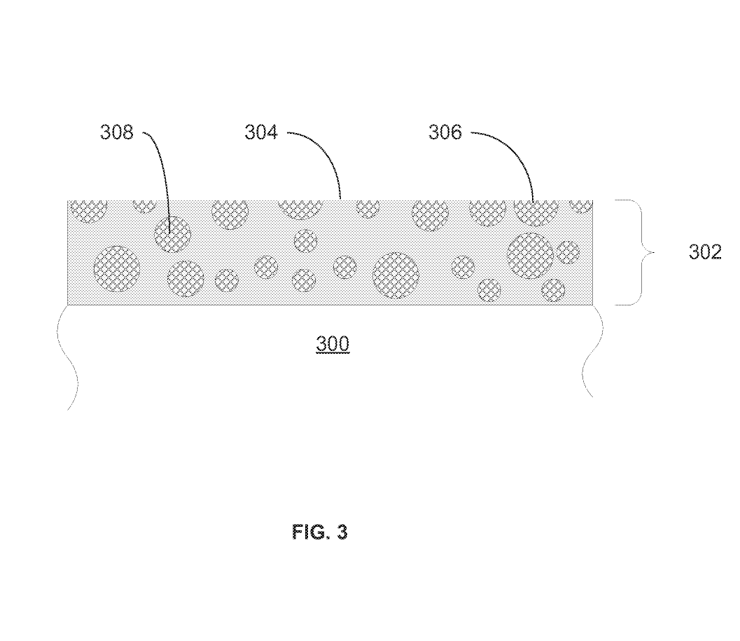

FIG. 3 illustrates a cross-sectional schematic of a substrate with a porous film formed thereon. FIG. 3 is meant to depict a substrate, 300, with a layer, 302, formed thereon using a PVD process (e.g. sputtering) and after the layer has been exposed to a binder material as discussed previously. The layer, 302, includes a matrix, 304, (formed from the deposited material), the matrix including internal porosity, 308, filled with the binder material, and surface porosity, 306, filled with the binder material. The layer will maintain its anti-glare properties while having improved mechanical and adhesion properties.

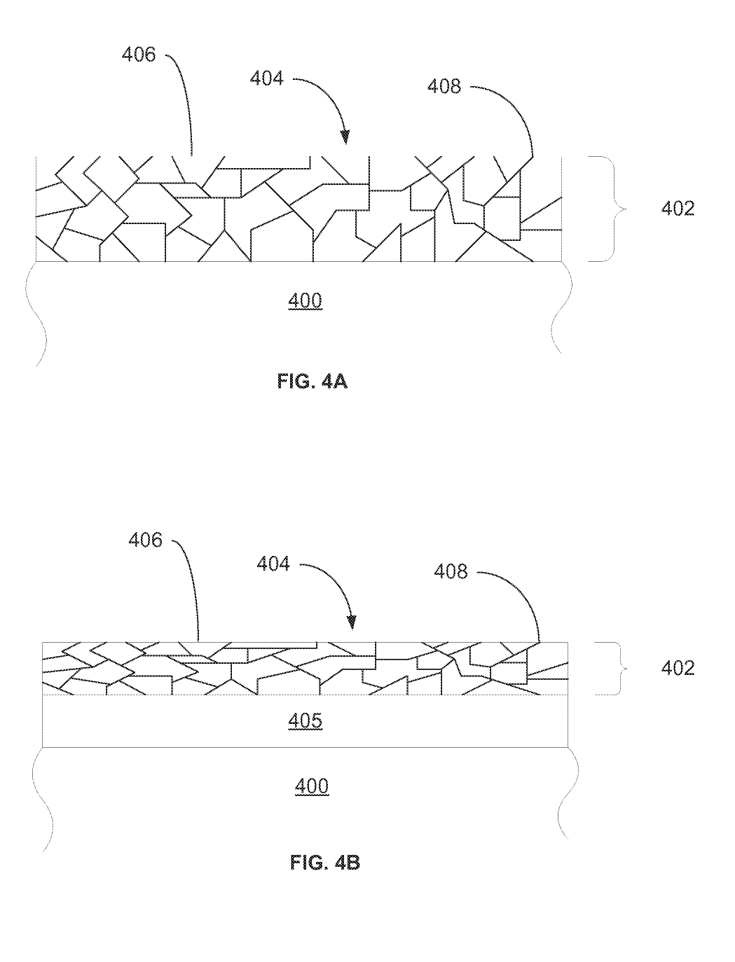

In some embodiments, inorganic metal oxide layers are deposited on a substrate using a PVD process (e.g. sputtering) as discussed previously. In some embodiments, inorganic metal oxide layers are deposited on a substrate using a chemical vapor deposition (CVD) process. The inorganic metal oxide layers can exhibit a polycrystalline structure and can be formed as a layer with a smooth surface (e.g. low surface roughness). Typically, the average grain size is less than about 0.2 microns. Examples of suitable inorganic metal oxides include the oxides of aluminum, boron, silicon, tin, titanium, zinc, or any combination thereof. FIG. 4A is meant to depict a substrate, 400, with a polycrystalline layer, 402, formed thereon using a PVD process (e.g. sputtering). The polycrystalline layer, 402, includes a surface, 404, including grains, 406. The surface, 404, is also intersected by grain boundaries, 408. Although illustrated as irregular shapes, those skilled in the art will understand that the grains within the material may have a more ordered shape and may exhibit orientation in a specific crystal direction. The size and volume fraction of the grains within the layer can be influenced by changing the process parameters of the PVD or CVD process. Examples of PVD process parameters that will influence the size and volume fraction of the grains within the layer include flux angle, power, plasma frequency (e.g. radio frequency (RF) versus direct current (DC), pressure, substrate temperature, sputtering gas composition, target-to-substrate spacing, and the like. Examples of CVD process parameters that will influence the size and volume fraction of the grains within the layer include substrate temperature, gas composition, gas flow rate, and the like. Typically, the layer, 402, has a thickness between 1 micron and 50 microns. Optionally, the layer can received a treatment such as a thermal anneal or a plasma surface treatment before subsequent processing.

In some embodiments, porogens can be introduced into the layer, 402. Porogens such as surfactants, silsesquioxanes, organic nanocrystals, organic nanoparticles, and other organic macromolecules such as polymers can be incorporated into the layer. The porogens can be used to introduce porosity and surface roughness during subsequent steps. Optionally, the layer can received a treatment such as a thermal anneal or a plasma surface treatment before subsequent processing.

In some embodiments, inorganic metal oxide layers are deposited on a substrate using a PVD process (e.g. sputtering) or CVD process as discussed previously. The inorganic metal oxide layers can exhibit a polycrystalline structure and can be formed as a layer with a smooth surface (e.g. low surface roughness). Examples of suitable inorganic metal oxides include the oxides of aluminum, boron, silicon, tin, titanium, zinc, or any combination thereof. The polycrystalline layer can be deposited on an amorphous or sub-layer having higher density and improved adhesion to the substrate than the polycrystalline layer. FIG. 4B is meant to depict a substrate, 400, with a sub-layer, 405, and a polycrystalline layer, 402, formed thereon using a PVD process (e.g. sputtering) or a CVD process. The sub-layer, 405, serves to give the coating structure (i.e. layers 405 and 402) increased mechanical strength and increased adhesion to the substrate. The polycrystalline layer, 402, includes a surface, 404, including grains, 406. The surface, 404, is also intersected by grain boundaries, 408. Although illustrated as irregular shapes, those skilled in the art will understand that the grains within the material may have a more ordered shape and may exhibit orientation in a specific crystal direction. The size and volume fraction of the grains within the layer can be influenced by changing the process parameters of the PVD or CVD process. Examples of process parameters that will influence the size and volume fraction of the grains within the layer include flux angle, power, plasma frequency (e.g. radio frequency (RF) versus direct current (DC), pressure, substrate temperature, sputtering gas composition, target-to-substrate spacing, and the like. Examples of CVD process parameters that will influence the size and volume fraction of the grains within the layer include substrate temperature, gas composition, gas flow rate, and the like. Typically, the coating structure (i.e. layers 405 and 402) has a thickness between 1 microns and 50 microns. Optionally, the layer can received a treatment such as a thermal anneal or a plasma surface treatment before subsequent processing.

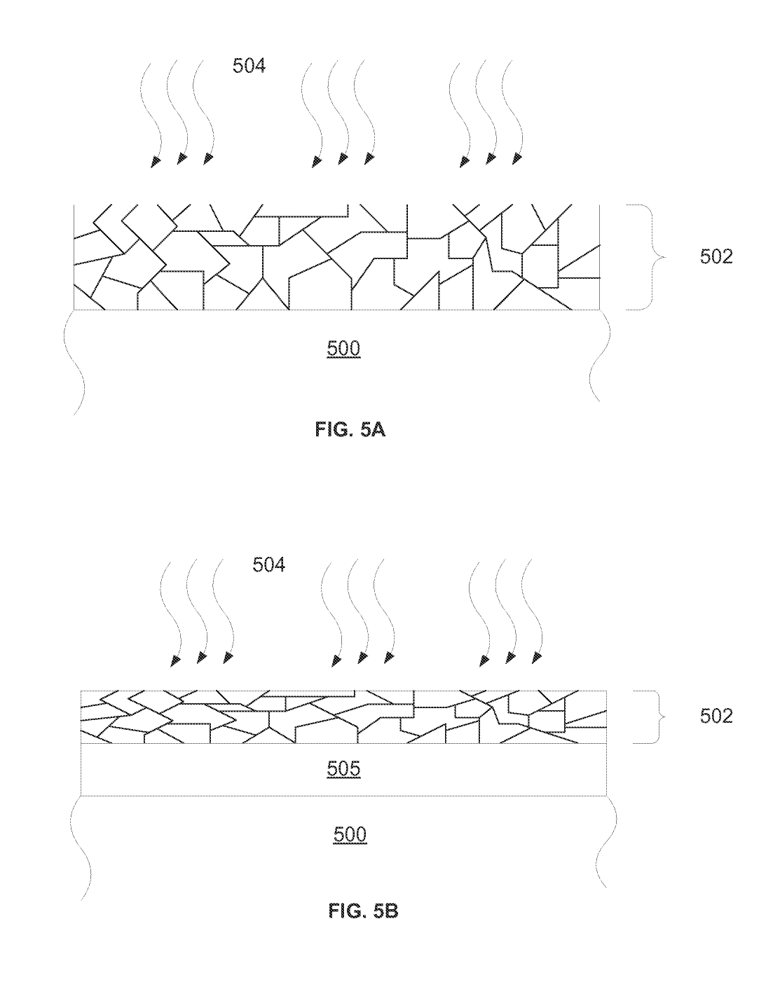

FIGS. 5A and 5B illustrate a cross-sectional schematic of a substrate with a polycrystalline layer, 502, formed thereon. In FIG. 5B, the coating structure further includes a sub-layer, 505, formed under the polycrystalline layer. FIGS. 5A and 5B are meant to depict a substrate, 500, with a polycrystalline layer, 502, formed thereon using a PVD process (e.g. sputtering) or CVD process. To increase the anti-glare properties of the polycrystalline layer, polycrystalline the layer, 502, may be exposed to a texturing reagent, 504. The texturing reagent, 504, may be applied in vapor or liquid form. The texturing reagent will penetrate into the polycrystalline layer and etch the layer. Generally, the etch rate of a material varies as a function of crystallographic orientation. The polycrystalline nature of the layer, 502, ensures that the resulting surface will have increased surface roughness. Examples of processes for texturing metal oxide materials are discussed in co-owned U.S. patent application Ser. No. 12/729,199, filed on Mar. 22, 2010, which claims priority to U.S. Provisional Patent Application No. 61/163,445, filed on Mar. 25, 2009, each of which is herein incorporated by reference for all purposes.

In some embodiments, the surface texturing may be performed using a texturing reagent that is an aqueous solution of an organic acid. In some embodiments, the organic acid is from the hydroxyl carboxylic acid family which includes carboxylic acids possessing 1-3 hydroxyl groups, such as glycolic acid, lactic acid, malonic acid, succinic acid, adipic acid, malic acid, tartaric acid, and citric acid. In some embodiments, the acids selected from this family of hydroxyl carboxylic acids for texturing are glycolic acid and citric acid. In some embodiments, the organic acid may be any of the following: 2-hydroxypropanoic acid, 2,3-dihydroxysuccinic acid, ethanedioic acid, amidosulphonic acid, 2-propyl methanesulphonate, methanecarboxylic acid, a-hydroxyacetic acid, 3-hydroxypentanedioic acid, trifluoroethanoic acid, trifluoroethanoic acid, 2-hydroxybenzoic acid, aminoethanoic acid. The acid concentration in the aqueous solution can be within the range of 10 mM-1.0 M. The temperature for the texturing process can be within the range of 10° C.-80° C., with more particularly in the range of 20° C.-70° C. The time duration for the texturing process can be in the range of 5 seconds to 30 minutes, with a more particular duration of 15 seconds to 10 minutes depending on the organic acid concentration and the temperature of the texturing reagent. Additionally, the texturing reagent itself may be varied by incorporating additives into the texturing reagent. In some embodiments, the additive may be an organic solvent. Other additives to the texturing reagent can include surfactants, including anionic, cationic, and polymeric surfactants.

In some embodiments, the surface texturing may be performed using a texturing reagent that is an aqueous solution of an inorganic acid. In some embodiments, the inorganic acid includes one or more of hydrochloric acid, sulfuric acid, nitric acid, phosphoric acid, and the like.

In some embodiments, the texturing reagent is formed of mixed acids. These embodiments of texturing reagent are formed by mixing a strong acid with a surface-passivating acid in order to control the texturing depth while achieving good light-scattering capability. The strong acids include hydrochloric acid, sulfuric acid, phosphoric acid (H₃PO₄), nitric acid, formic acid, acetic acid, trifluoacetic acid, sulfamic acid, methanesulfonic acid, and any acid that does not form surface passivation on metal oxide surface. The surface-passivating acid may be any of the hydroxyl carboxylic acids mentioned above or an organic acid that can form a surface passivation layer with a metal oxide, such as oxalic acid, and the derivatives of various benzenesulfonic acids. The preferred strong etch acids include hydrochloric acid, sulfuric acid, and phosphoric acid; the preferred surface-passivating acids include oxalic acid, lactic acid, and tartaric acid. The acid concentration range, the texturing bath temperature, and the texturing duration are the same as mentioned above for the hydroxyl carboxylic acid etch alone.

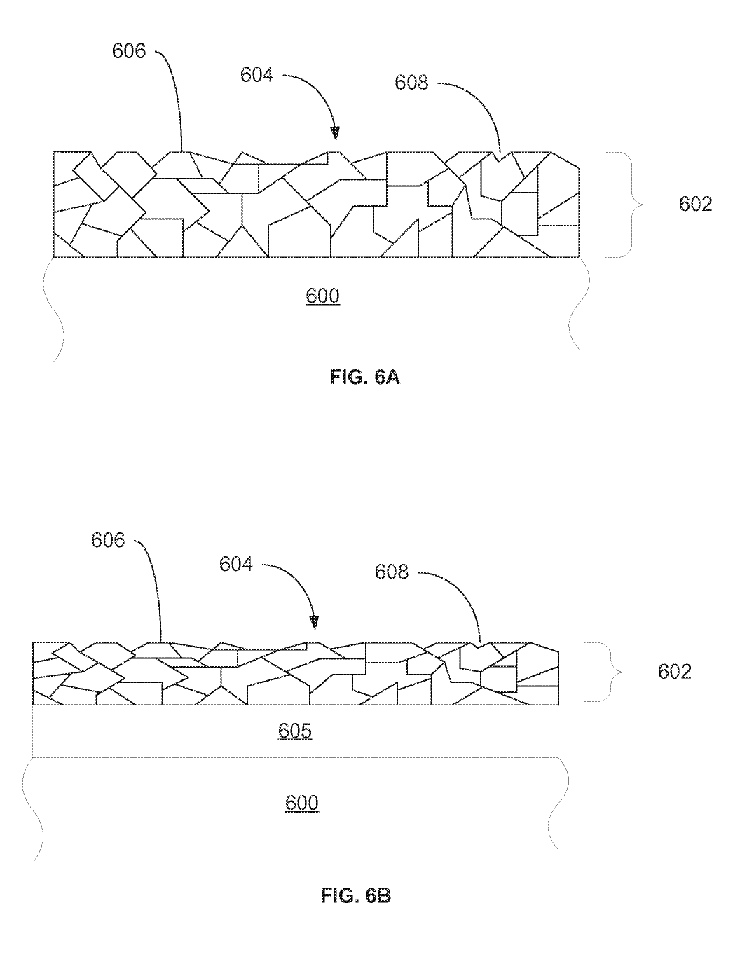

FIGS. 6A and 6B illustrate a cross-sectional schematic of a substrate with a textured film formed thereon. FIGS. 6A and 6B are meant to depict a substrate, 600, with a polycrystalline layer, 602, formed thereon using a PVD process (e.g. sputtering) or CVD process and after the polycrystalline layer has been exposed to a texturing reagent as discussed previously. In FIG. 6B, the coating structure further includes a sub-layer, 605, formed under the polycrystalline layer. The polycrystalline layer, 602, includes a surface, 604, the surface including grains, 606, and surface facets, 608. The polycrystalline layer will maintain its anti-glare properties while having improved mechanical and adhesion properties.

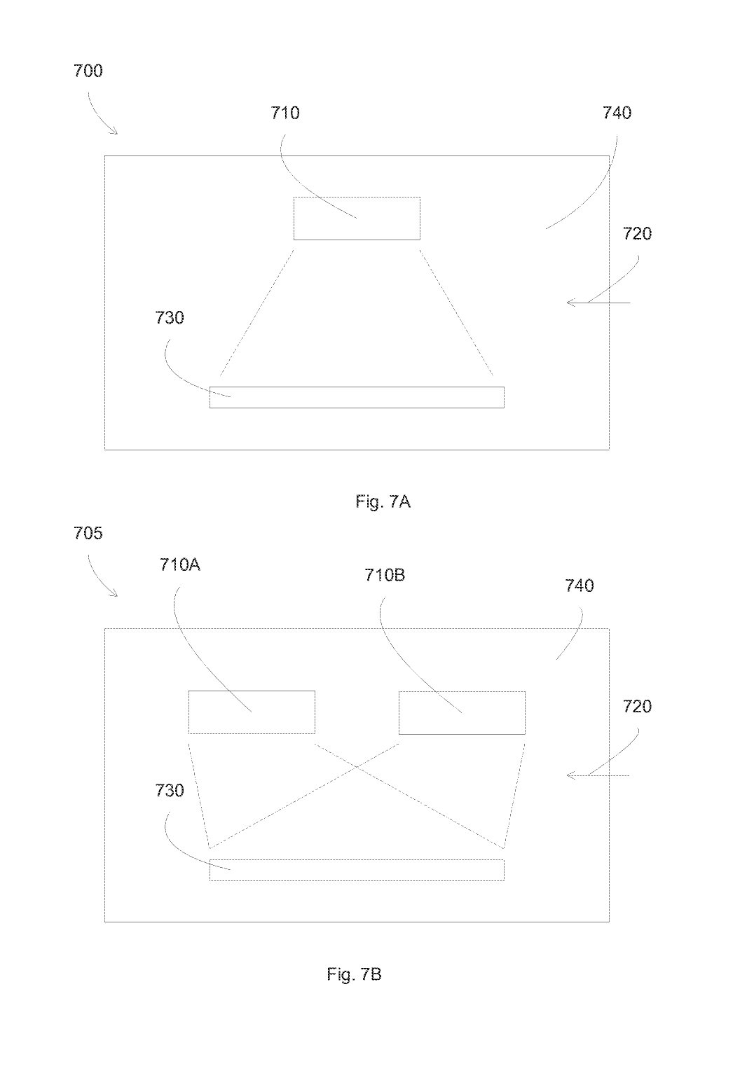

FIGS. 7A and 7B illustrate exemplary physical vapor deposition (PVD) systems according to some embodiments. In FIG. 7A, the PVD system, also commonly called sputter system or sputter deposition system, 700, includes a housing that defines, or encloses, a processing chamber, 740, a substrate, 730, a target assembly, 710, and reactive species delivered from an outside source, 720. The substrate can be stationary, or in some manufacturing environments, the substrate may be in motion during the deposition processes. During deposition, the target is bombarded with argon ions, which releases sputtered particles toward the substrate, 730. The sputter system, 700, can perform blanket deposition on the substrate, 730, forming a deposited layer that covers the whole substrate, (e.g., the area of the substrate that can be reached by the sputtered particles generated from the target assembly, 710). A reactive gas such as oxygen or nitrogen may be added to the sputtering atmosphere to form metal compounds such as metal oxide, metal nitride, or metal oxy-nitride layers on the substrate.

In FIG. 7B, a sputter deposition chamber, 705, comprises two target assemblies, 710A and 710B, disposed in the processing chamber, 740, containing reactive species delivered from an outside source, 720. The target assemblies, 710A and 710B, can comprise different materials to deposit an alloy or multi-component layer on substrate, 730. This configuration is exemplary, and other sputter system configurations can be used, such as a single target as above. As discussed previously, reactive gases can be used to form metal compound layers.

The materials used in the target assembly, 710 (FIG. 7A), may, for example, include aluminum, silicon, tin, titanium, or any combination thereof (i.e., a single target may be made of an alloy of several metals). Additionally, the materials used in the targets may include oxygen, nitrogen, or a combination of oxygen and nitrogen in order to form the oxides, nitrides, and oxynitrides described above. Additionally, although only one target assembly, 710, is shown (FIG. 7A), additional target assemblies may be used (e.g. FIG. 7B). As such, different combinations of targets may be used to form the different layers described above.

The sputter deposition system, 700, can comprise other components, such as a substrate support for supporting the substrate. The substrate support can comprise a vacuum chuck, electrostatic chuck, or other known mechanisms. The substrate support can be capable of rotating around an axis thereof that is perpendicular to the surface of the substrate. In addition, the substrate support may move in a vertical direction or in a planar direction. It should be appreciated that the rotation and movement in the vertical direction or planar direction may be achieved through known drive mechanisms which include magnetic drives, linear drives, worm screws, lead screws, a differentially pumped rotary feed through drive, etc.

In some embodiments, the substrate support includes an electrode which is connected to a power supply, for example, to provide a RF or dc bias to the substrate, or to provide a plasma environment in the process housing, 740. The target assembly, 710, can include an electrode which is connected to a power supply to generate a plasma in the process housing. The target assembly, 710, is preferably oriented towards the substrate, 730.

The sputter deposition system, 700, can also comprise a power supply coupled to the target electrode. The power supply provides power to the electrodes, causing material to be sputtered from the target. During sputtering, inert gases, such as argon or krypton, may be introduced into the processing chamber, 740, through the gas inlet, 720. In some embodiments in which reactive sputtering is used, reactive gases may also be introduced, such as oxygen and/or nitrogen, which interact with particles ejected from the targets to form oxides, nitrides, and/or oxy-nitrides on the substrate as described above.

The sputter deposition system, 700, can also comprise a control system (not shown) having, for example, a processor and a memory, which is in operable communication with the other components and configured to control the operation thereof in order to perform the methods described herein.

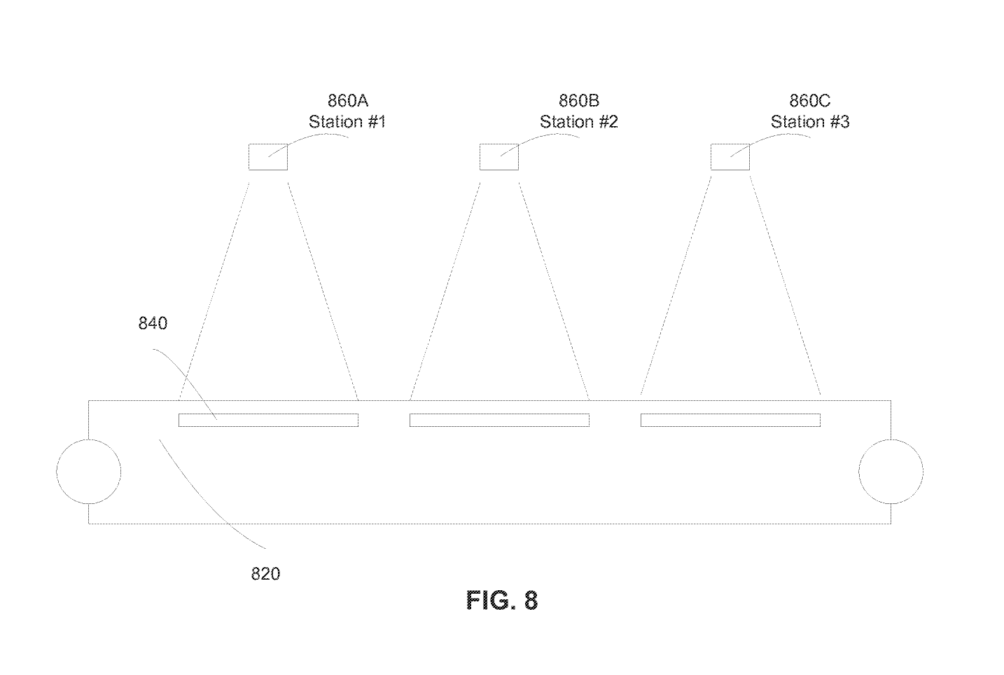

FIG. 8 illustrates an exemplary in-line deposition (e.g. sputtering) system that might be used to deposit coating on large area substrates according to some embodiments. FIG. 8 illustrates a system with three deposition stations, but those skilled in the art will understand that any number of deposition stations can be supplied in the system. For example, the three deposition stations illustrated in FIG. 8 can be repeated and provide systems with 6, 9, 12, etc. targets, limited only by the desired layer deposition sequence and the throughput of the system. A transport mechanism, 820, such as a conveyor belt or a plurality of rollers, can transfer substrate, 840, between different deposition stations. For example, the substrate can be positioned at station #1, comprising a target assembly, 860A, then transferred to station #2, comprising target assembly, 860B, and then transferred to station #3, comprising target assembly, 860C. Station #1 can be configured to deposit a first layer. Station #2 can be configured to deposit a second layer with the same or different composition. Station #3 can be configured to deposit a third layer with the same or different composition.

Although only a single target is illustrated in each deposition station of FIG. 8, in some embodiments, a deposition station may include more than one target to allow the co-sputtering of more than one material as discussed previously. As discussed previously, each deposition station may have the ability to also use reactive gases to deposit metal compound layers.

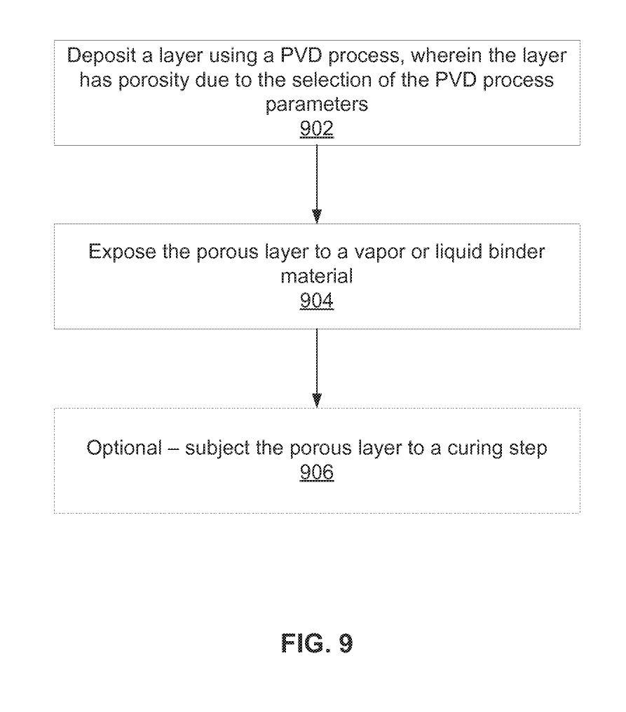

FIG. 9 illustrates a flow chart describing methods according to some embodiments. In step 902, a layer is deposited using a PVD process, wherein the layer is porous due to the selection of the PVD process parameters. Examples of PVD process parameters that will influence the size and volume fraction of the porosity within the layer include flux angle, power, plasma frequency (e.g. radio frequency (RF) versus direct current (DC), pressure, substrate temperature, sputtering gas composition, target-to-substrate spacing, and the like. In step 904, the porous layer is exposed to a vapor or liquid binder material, wherein the binder material fills the pores within the layer. In step 906, an optional curing step may be applied to the layer. The curing step may be a thermal curing step or a chemical curing step.

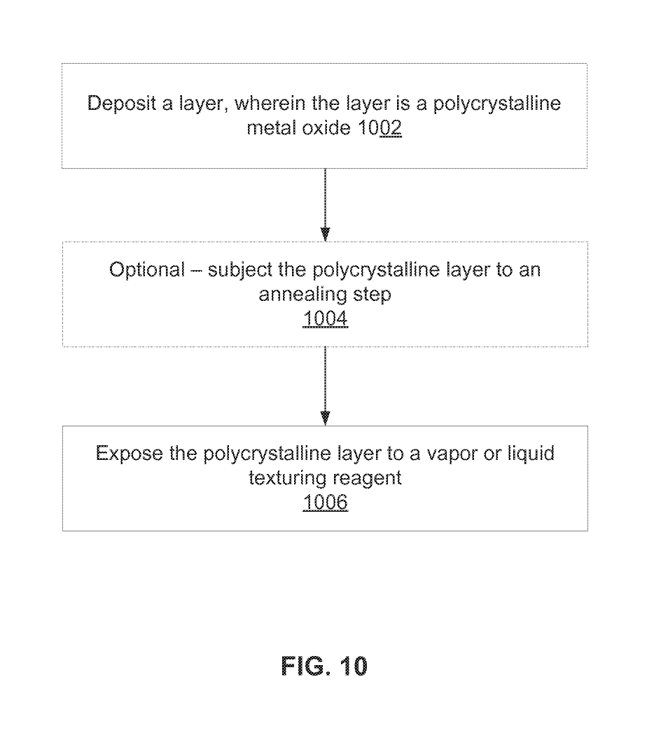

FIG. 10 illustrates a flow chart describing methods according to some embodiments. In step 1002, a metal oxide layer is deposited using a PVD or CVD process, wherein the metal oxide layer is polycrystalline due to the selection of the PVD or CVD process parameters. In step 1004, an optional anneal step may be applied to the metal oxide layer. In step 1006, the metal oxide layer is exposed to a vapor or liquid texturing reagent.

Although the foregoing examples have been described in some detail for purposes of clarity of understanding, the invention is not limited to the details provided. There are many alternative ways of implementing the invention. The disclosed examples are illustrative and not restrictive.

1. A method for forming an anti-glare coating, the method comprising:
depositing a layer above a substrate, wherein the layer comprises pores;
exposing the layer to a binder material
wherein the binder material penetrates into the layer and fills the pores; and
exposing the layer to a texturing reagent to etch the layer thereby increasing the surface roughness of the layer and enhancing an anti-glare property of the layer.

2. The method of claim 1 further comprising subjecting the layer to a curing step after exposing the layer to the binder material.

3. The method of claim 2 wherein the curing step is a thermal curing process or a chemical curing process.

4. The method of claim 1 wherein the layer is deposited using a physical vapor deposition process, wherein the physical vapor deposition process parameters are selected to create the pores in the layer during the deposition.

5. The method of claim 4 wherein the physical vapor deposition process parameters comprise at least one of flux angle, power, plasma frequency, pressure, substrate temperature, sputtering gas composition, or target-to-substrate.

6. The method of claim 1 wherein the binder material comprises one or more of inorganic silanes, organic silanes, silane vapors, siloxanes, silazanes, sol formulations containing silanes, or combinations thereof.

7. The method of claim 1 wherein the layer comprises oxides, nitrides, or oxynitrides of aluminum, silicon, tin, titanium, zinc, or combination thereof.

8. The method of claim 1 wherein the layer is formed as a homogeneous layer.

9. The method of claim 1 wherein the layer is formed as a nanolaminate.
